(19) United States
(12) Patent Application Publication
(10) Pub. No.: US 2008/0194070 A1
(43) Pub. Date: Aug. 14, 2008

(54) Metal-oxide-semiconductor transistor device, manufacturing method thereof, and method of improving drain current thereof

(76) Inventors: Hung-Lin Shih, Hsinchu City (TW); Jih-Shun Chiang, Hsinchu City (TW); Hsien-Liang Meng, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/108,519

(22) Filed: Apr. 24, 2008

Related U.S. Application Data
(62) Division of application No. 11/458,393, filed on Jul. 19, 2006.

(51) Int. Cl. H01L 21/336

(52) U.S. Cl. 438/285; 438/296; 257/E21.405; 257/E21.409

(57) ABSTRACT

A method of manufacturing a metal-oxide-semiconductor transistor device is disclosed, in which, an insulation region is formed to define the insulation region and an active region, wherein the active region is adjacent to the insulation region and electrically insulated by the insulation region. A selective epitaxial process is performed to form an epitaxial layer on the active region; wherein the epitaxial layer laterally extends onto a surface of a peripheral portion of the insulation region. Thereafter, a doped well is formed in the semiconductor substrate of the active region. A gate structure is formed on the epitaxial layer. Finally, a drain/source region is formed in the semiconductor substrate and the epitaxial layer at a side of the gate structure.

### CROSS REFERENCE TO RELATED APPLICATIONS

This is a divisional application of U.S. patent application Ser. No. 11/458,393 filed on Jul. 19, 2006, and the contents of which are included herein by reference.

### BACKGROUND OF THE INVENTION

1. Field of the Invention

The present invention relates to a semiconductor device and a manufacturing method thereof, and a method of improving drain current thereof, and more particularly, to a metal-oxide-semiconductor transistor device, a manufacturing method of a metal-oxide-semiconductor transistor device, and a method of improving drain current of a metal-oxide-semiconductor transistor device.

2. Description of the Prior Art

For decades, chip manufacturers have made metal-oxide-semiconductor (MOS) transistors faster by making them smaller. As the semiconductor processes advance to very deep sub micron era such as 65-nm node or beyond, how to increase the driving current for MOS transistors has become a critical issue.

To attain higher performance of the semiconductor device, attempts have been made to use a strained silicon (Si) layer for increasing the mobility of the electrons or the holes. For example, taking advantage of the lattice constant of SiGe layer different from that of Si, a strain occurs in the silicon layer growing on the SiGe layer. A type of strained Si-FET may be formed through forming a relaxed SiGe layer on a silicon-on-insulation (SOI) substrate, and then forming a silicon epitaxial layer on the relaxed SiGe layer. Since SiGe has a larger lattice constant than Si, the band structure of Si is altered, to increase the mobility of the carriers.

Other attempts have been made to use germanium embedded in a source/drain region formed by selective epitaxial growth as a compressive strained silicon film to enhance electron mobility in a PMOS transistor, after a gate is formed. In NMOS transistor manufacturing processes, carbon is embedded in a source/drain region formed by selective epitaxial growth as a tensile strained silicon film to enhance electron mobility in a NMOS transistor.

FIG. 1 shows a schematic top-view diagram of conventional metal-oxide-semiconductor transistor devices. FIG. 2 shows a schematic cross-section view diagram taken along the line AA′ in FIG. 1. The description is referred to a CMOS transistor device structure. CMOS transistor device 1 comprises a semiconductor substrate. The semiconductor substrate comprises an active region 13 and an insulation region 16 surrounding the active region 13 for electric insulation. A gate structure comprising, for example, a gate insulation layer 18, a gate electrode layer 20, and a spacer 22, is disposed on the active region 13. The active region 13 may comprise a well 14 or 15. Accordingly, a channel width of the device is the width of the gate electrode layer intersecting the active region, that is, the channel width of the conventional MOS transistor devices is limited to the width of the active region 13.

There are many techniques to improve mobility of carriers. For example, FIG. 3 shows a schematic cross-section view diagram of another conventional MOS transistor device, which further comprising a metal salicide layer 25 and a contact etch stop layer (CESL) 21. By the application of the stress, the channel on the semiconductor substrate has a tensile or compressive strain to improve mobility. However, for the conventional techniques improving mobility of carriers, the channel width obtained still depends on and is limited to the ultimate size of devices obtained through the limitation of the techniques, such as the limitation of photolithography and the limitation of the gap filling during the manufacture of shallow trench isolations.

Therefore, there is still a need for a MOS transistor device and a method of manufacturing the same to improve performance of the device.

### SUMMARY OF THE INVENTION

An object of the present invention is to provide a metal-oxide-semiconductor transistor device, a method of manufacturing a metal-oxide-semiconductor transistor device, and a method of improving drain current of a metal-oxide-semiconductor transistor device. The MOS transistor device according to the present invention comprises an epitaxial layer between the active region of the semiconductor substrate and the gate structure, and a peripheral portion of the epitaxial layer is over a peripheral portion of the insulation region, such that a channel width can be obtained wider than the width of the active region. Therefore, drain current is improved.

The metal-oxide-semiconductor transistor device according to the present invention comprises a semiconductor substrate, a gate structure, and an epitaxial layer. The semiconductor substrate comprises an active region and an insulation region surrounding the active region for electric insulation. The gate structure is disposed on the active region. The epitaxial layer is between the active region and the gate structure and a peripheral portion of the epitaxial layer is over a peripheral portion of the insulation region.

The method of manufacturing a metal-oxide-semiconductor transistor device according to the present invention comprises steps as follows. First, a semiconductor substrate is provided. Next, an insulation region is formed to define the insulation region and an active region, wherein the active region is adjacent to the insulation region and electrically insulated by the insulation region. Subsequently, a selective epitaxial process is performed to form an epitaxial layer on the active region; wherein the epitaxial layer laterally extends onto a surface of a peripheral portion of the insulation region. Thereafter, a doped well is formed in the semiconductor substrate of the active region. A gate structure is formed on the epitaxial layer. Finally, a drain/source region is formed in the semiconductor substrate and the epitaxial layer at a side of the gate structure.

The method of manufacturing a metal-oxide-semiconductor transistor device according to the present invention comprises steps as follows. First, a semiconductor substrate is provided. Next, an insulation region and a doped well are formed such that the doped well is surrounded by the insulation region. Subsequently, a selective epitaxial process is performed to form an epitaxial layer on the doped well; wherein the epitaxial layer laterally extends onto a surface of a peripheral portion of the insulation region. Thereafter, a gate structure is formed on the epitaxial layer. Finally, drain/source region is formed in the doped well and the epitaxial layer at a side of the gate structure.

The method of improving drain current of a metal-oxide-semiconductor transistor device according to the present invention comprises steps as follows. First, the metal-oxide-semiconductor transistor device comprises a semiconductor substrate and a gate structure. The semiconductor substrate comprises an insulation region and an active region surrounded by the insulation region for electric insulation. The method comprises a step of forming a selective epitaxial layer on the active region, after the insulation region is formed and before the gate structure is formed. The epitaxial layer laterally extends onto a surface of a peripheral portion of the insulation region; thereby a channel width of the metal-oxide-semiconductor transistor device is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic top-view diagram of conventional MOS transistor devices;

FIG. 2 shows a schematic cross-section view diagram taken along the line AA′ in FIG. 1;

FIG. 3 shows a schematic cross-section view diagram of another conventional MOS transistor device;

FIG. 4 shows a schematic top-view diagram of a plurality of the MOS transistor devices according to the present invention;

FIG. 5 shows a schematic cross-section view diagram taken along the line BB′ in FIG. 4;

FIG. 6 shows a schematic cross-section view diagram of another embodiment of the MOS transistor devices according to the present invention;

FIGS. 7 to 13 show schematic cross section view diagrams for an embodiment of the method of manufacturing a MOS transistor device according to the present invention;

FIG. 14 shows a flow chart illustrating embodiments of the method of manufacturing the MOS transistor device according to the present invention;

FIG. 15 shows a transmission electron microscope photograph of a semi-finished product after the epitaxial layer is formed in an embodiment of the method according to the present invention;

FIG. 16 shows a graph obtained by plotting Iₒₙ versus Ldrawn of the HVT PMOS transistor devices made by the method according to the present invention and the conventional techniques, respectively;

FIG. 17 shows a graph obtained by plotting Iₒₙ versus Ldrawn of the HVT NMOS transistor devices made by the method according to the present invention and the conventional techniques, respectively;

FIG. 18 shows a universal curve obtained by plotting I_{off} versus Iₒₙ of the HVT NMOS transistor devices made by the method according to the present invention and the conventional techniques, respectively; and

FIG. 19 shows a universal curve obtained by plotting I_{off} versus Iₒₙ of the HVT PMOS transistor devices made by the method according to the present invention and the conventional techniques, respectively.

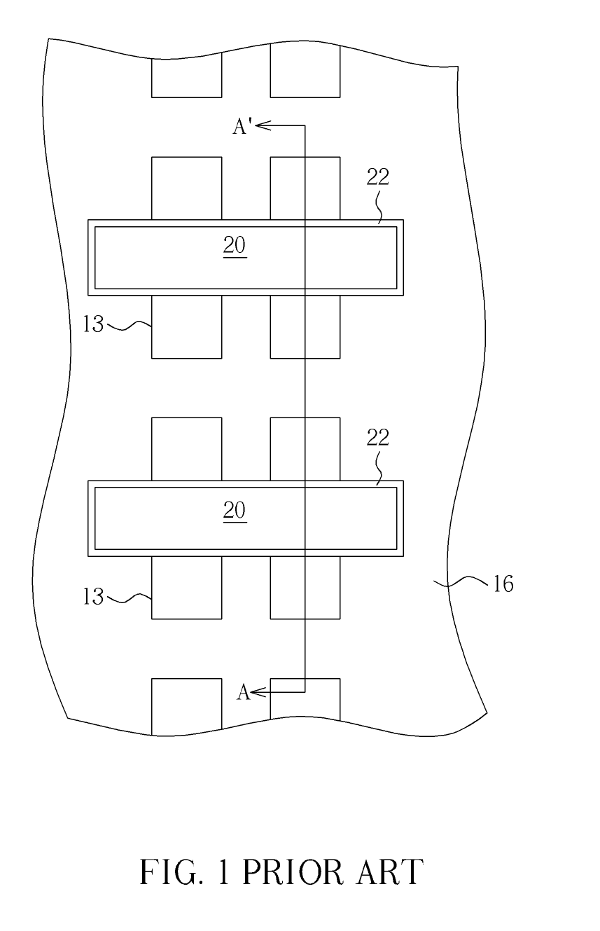

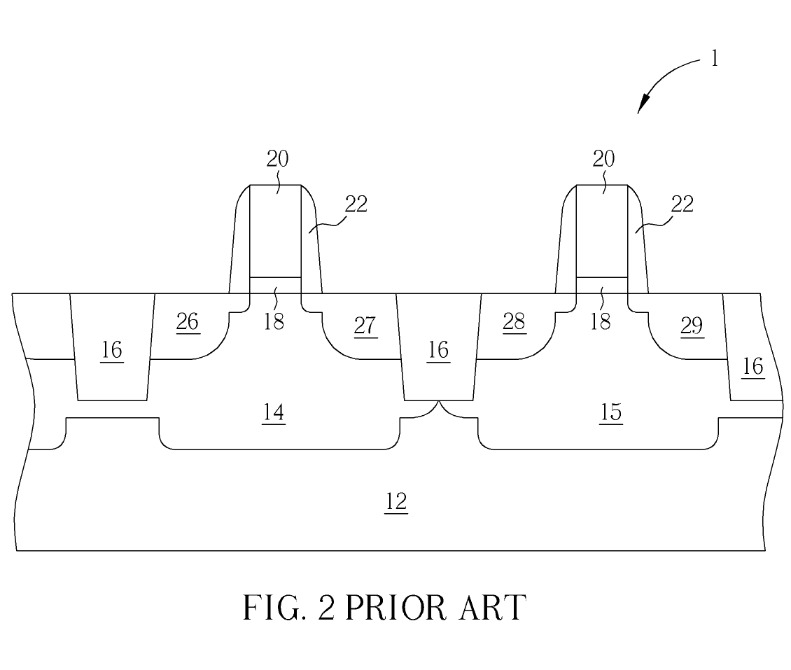

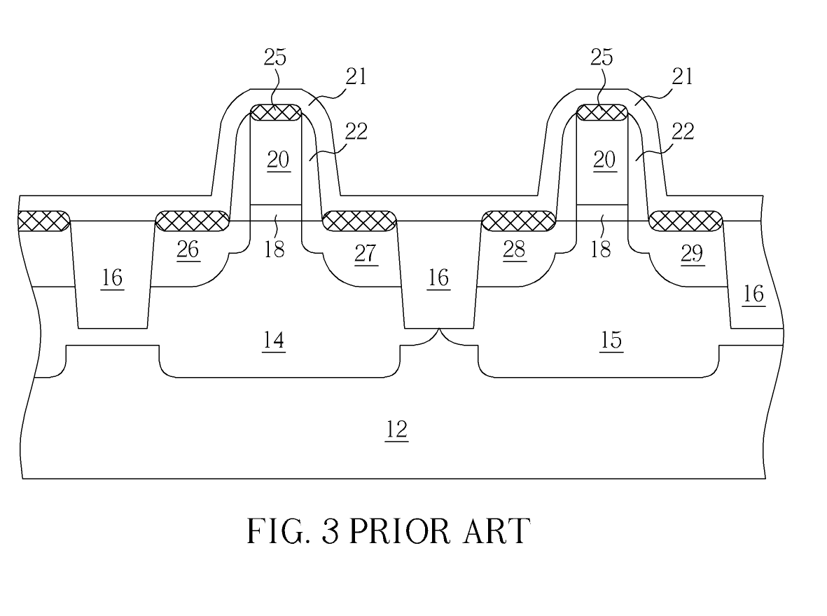

### DETAILED DESCRIPTION

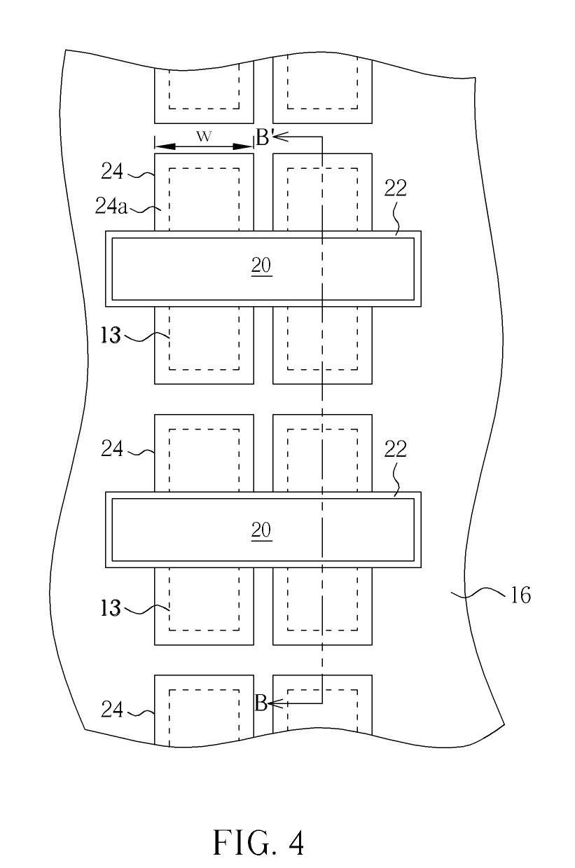

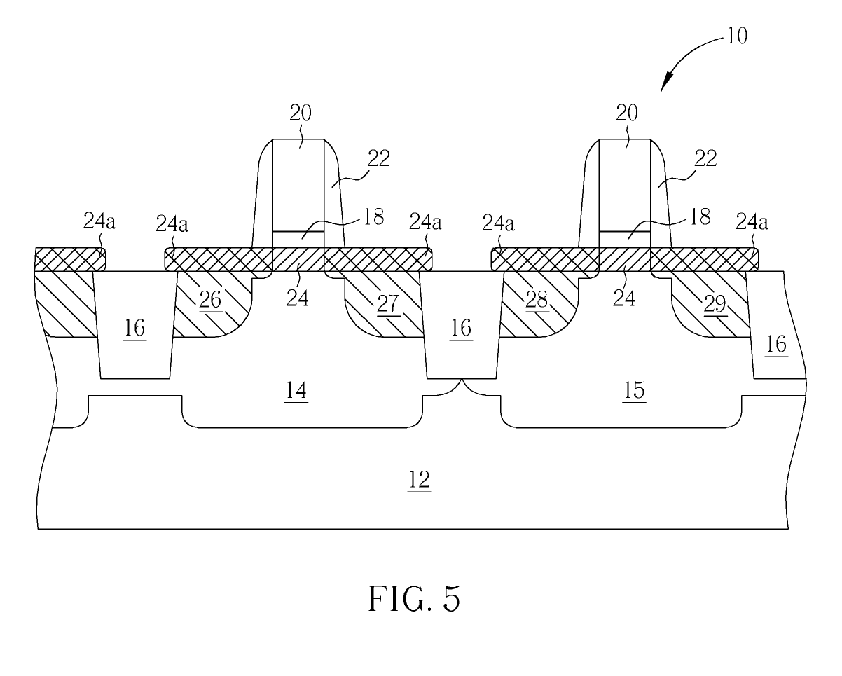

The metal-oxide-semiconductor transistor device according to the present invention may be an NMOS, a PMOS, or a CMOS transistor device. FIG. 4 shows a schematic top-view diagram of a plurality of the MOS transistor device according to the present invention. FIG. 5 shows a schematic cross-section view diagram taken along the line BB′ in FIG. 4. The description is referred to a CMOS transistor device structure. Like number numerals designate similar or the same parts, regions or elements. It is to be understood that the drawings are not drawn to scale and are served only for illustration purposes. CMOS transistor device 10 comprises a semiconductor substrate. The semiconductor substrate comprises an active region 13 and an insulation region 16 surrounding the active region 13 for electric insulation. A gate structure comprising, for example, a gate insulation layer 18, a gate electrode layer 20, and a spacer 22, is disposed on the active region 13. The epitaxial layer 24 is between the active region 13 and the gate structure and a peripheral portion 24a of the epitaxial layer 24 is over a peripheral portion of the insulation region 16.

In the CMOS transistor device 10, the semiconductor substrate generally comprises a silicon layer 12, such as silicon substrate or silicon-on-insulator (SOI) substrate, but not limited thereto. The insulation region 16 may be, for example, a shallow trench isolation comprising a material, such as silicon oxide, for electric insulation of the active region 13 surrounded by the insulation region 16. The active region 13 may comprise a P type well or an N type well, P type well 14 for an NMOS transistor device and N type well 15 for a PMOS transistor device. The active region 13 may comprise drain/source regions 26 and 27 or drain/source regions 28 and 29, formed respectively in the well 14 or 15 and the epitaxial layer 24 at two sides of the gate structure. In an NMOS transistor device, the drain/source regions 26 and 27 are doped with N type dopants. In a PMOS transistor device, the drain/source regions 28 and 29 are doped with P type dopants. The drain/source region may further comprise a lightly doped drain region. The epitaxial layer 24 is disposed above the active region 13 and under the gate structure, that is, between the well and the gate structure. It should be noted that the epitaxial layer does not cover the entire insulation region 16, but is selectively formed on the surface of the substrate having a crystal structure, and only a peripheral portion 24a laterally extends onto a peripheral portion of the insulation region 16.

In such structure clearly shown in FIG. 4, the channel width, w, is wider than the width of the active region 13 which is the channel width in the conventional technique, such that the I_{d} is increased and the performance of the transistor device is improved. In PMOS transistor devices, the epitaxial layer may comprise Si, SiC, a combination of Si and SiC, or the like. In NMOS transistor devices, the epitaxial layer may comprise Si, SiGe, a combination of Si and SiGe, or the like. The epitaxial layer may be further lightly doped. The thickness of the epitaxial layer is not particularly limited and may be as desired. For example, it may be in a range of 50 to 500 Å. The thicker the epitaxial layer, the more the peripheral portion of the epitaxial layer laterally extends onto the peripheral portion of the insulation region, and the wider the channel width obtained. But, it may be noted that two peripheral portions of the epitaxial layer from two adjacent MOS transistor device are not allowed to merge together or contact with each other or be too close to affect the electric insulation requirement for the two MOS transistor devices.

The gate structure may comprise a gate insulation layer 18 and a gate electrode layer 20. The gate insulation layer may comprise dielectric material such silicon oxide. The gate electrode layer may comprise a conductive material such as poly-silicon. The gate structure may further comprise a spacer 22 for forming a lightly doped extension region in the drain/source region. Thereafter, the spacer may be kept in the structure or removed. The gate structure may further comprise an L-shaped liner formed between the spacer and the gate electrode layer and semiconductor substrate (not shown).

The MOS transistor device according to the present invention has a structure characterized by the epitaxial layer between the gate structure and the active region of the semiconductor substrate and the peripheral portion of the epitaxial layer lateral extends onto a peripheral portion of the insulation region. Therefore, the channel width is increased.

It is known that drain current of a MOS transistor device can be calculated from the channel length (L) and the channel width (W), which are determined by the manufacturing process. When the transistor is operated in a saturation mode, the magnitude of I_{d} is determined after the channel length and the channel width are determined, as shown by the equation as follows:

$${I}_{d} = \frac{W}{L} μ {C}_{ox} \frac{{( {V}_{g} - {V}_{t} )}^{2}}{2}$$

W: channel width

L: channel length

μ: mobility

Cₒₓ: capacitance

V_{g}: gate voltage

Vₜ: threshold voltage

Therefore, when the channel width is increased, the I_{d} is increased. The structure of the MOS transistor device according to the present invention as described above is characterized by the structure with a selective epitaxial layer, such that the channel width is wider than that obtained by conventional techniques. Therefore, I_{d} is improved as compared to I_{d} obtained by the conventional techniques. When the MOS transistor device is manufactured according to the present invention, a formation of the selective epitaxial layer is performed in addition to the processes used in conventional manufacturing techniques. The formation of the selective epitaxial layer does not affect the conventional processes, but can further increase I_{d} compared to that obtained from the conventional processes, to more increase the performance.

Furthermore, since the upper layer of the channel under the gate insulation layer comprises a pure epitaxial layer, the concentration of the dopants diffused thereto will be less as compared to the concentration of the dopants in semiconductor substrate caused by the un-avoided diffusion in the process. Therefore, the Vₜ is advantageously decreased and the I_{d} can be increased.

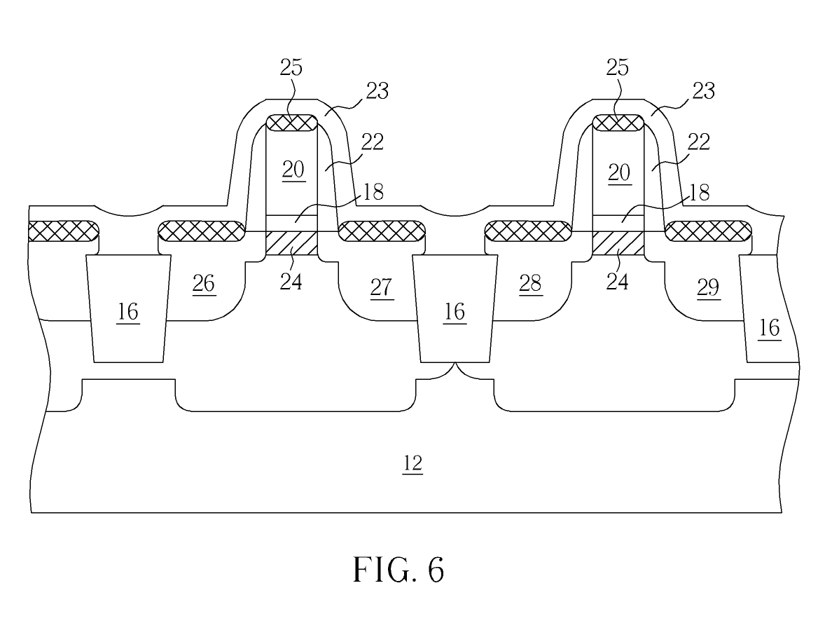

The MOS transistor device based on such structure can be used in various MOS transistor devices, such as the MOS transistor device shown in FIG. 6 may further comprise metal salicide layer 25 or a contact etch stop layer (CESL) 23. The contact etch stop layer 23 may comprise a uniformly deposited silicon nitride cap layer having a thickness preferably ranging from 30 to 2000 Å.

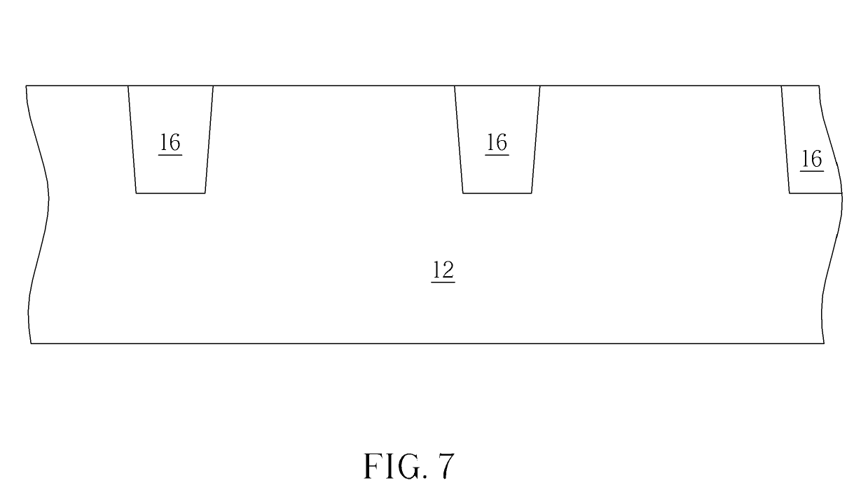

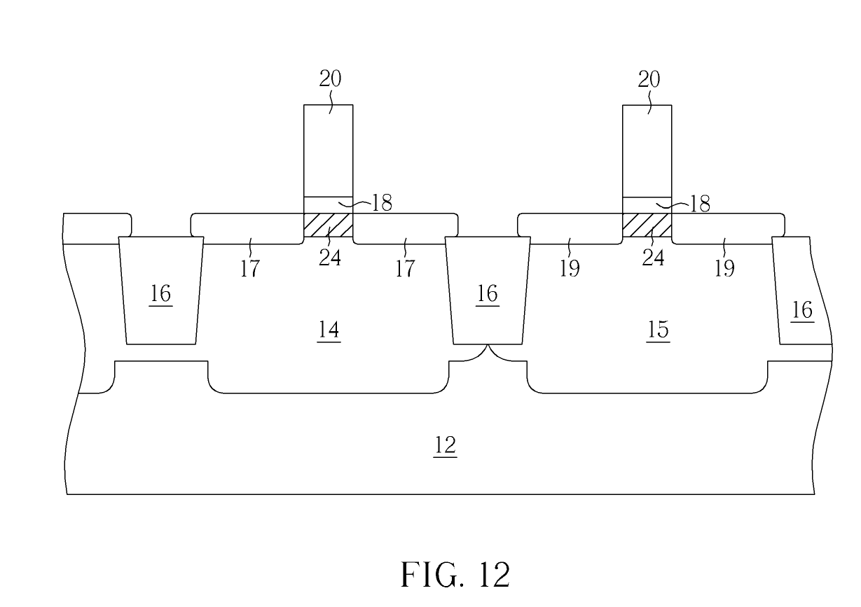

Please refer to FIGS. 7 to 13 for description of the method of manufacturing the MOS transistor device according to the present invention. The MOS transistor device may be an NMOS, PMOS, or CMOS transistor device. FIGS. 7 to 13 show schematic cross section view diagrams for an embodiment of the method of manufacturing a MOS transistor device according to the present invention. Like number numerals designate similar or the same parts, regions or elements. It is to be understood that the drawings are not drawn to scale and are served only for illustration purposes.

Referring to FIG. 7, first, a semiconductor substrate comprising a silicon layer 12 is provided. An insulation region 16 is formed in the silicon layer 12. The insulation region may be for example a shallow trench isolation. The steps for forming the shallow trench isolation may comprise, first, forming an oxide barrier layer on the surface of the silicon layer 12 using a thermal oxidation process to protect the active region. Next, a silicon nitride layer may be formed on the oxide barrier layer by chemical vapor deposition. Thereafter, a photolithography is performed to form a patterned photo-resist layer on the silicon nitride layer for etching the trench. After cleaning and drying, a low-pressure chemical vapor deposition is performed to fill oxide in the trench. Subsequently, a chemical mechanical polishing process is performed to remove excess portion of the oxide layer. Thereafter, the silicon nitride layer is removed with hot phosphorous acid to expose the silicon layer 12. Thus, an insulation region 16 is formed. The insulation region 16 surrounds the active region for electric insulation.

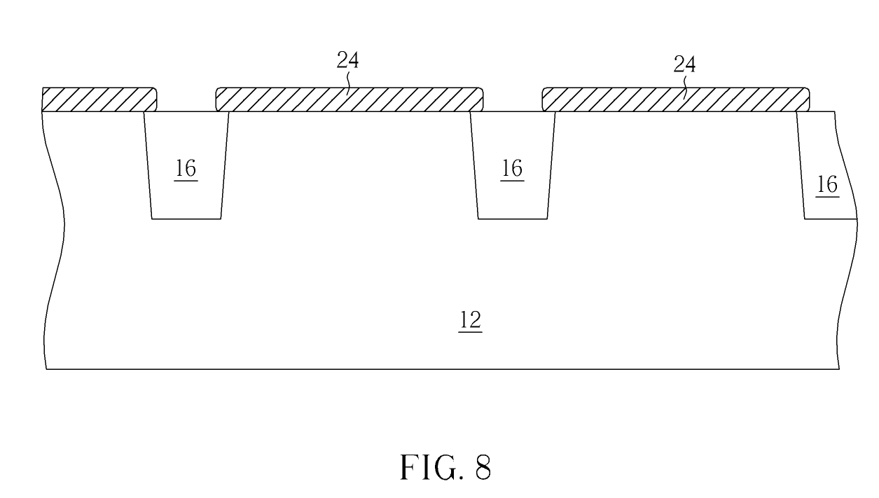

In the method according to the present invention, the formation of the epitaxial layer is performed after the insulation region 16 is formed and the silicon nitride layer is removed to expose the silicon layer 12, and may be performed before and after the formation of well. The formation of the epitaxial layer is preferably performed immediately after the silicon layer 12 is exposed, to prevent the crystal structure of the silicon layer from damage affecting the quality of the epitaxial crystal. Please refer to FIG. 8 showing, after the insulation region 16 is formed and before the well is formed, an epitaxial layer 24 is formed on the silicon layer 12, which is accomplished by a selective epitaxial growth (SEG).

In a preferred embodiment according to the present invention, the silicon epitaxial layer is formed by a selective epitaxial growth using gasses comprising, for example, dichlorosilane (DCS), hydrochloride (HCl), and hydrogen, at a process temperature lower than 800° C., through, for example, a reduced pressure chemical vapor deposition (RPCVD). In another embodiment of the present invention, the gasses used in the selective epitaxial growth process may comprise for example silane (SiH₄) and chloride (Cl₂). Other process, such as MBE (molecular beam epitaxy) or UHVCVD (ultra high vacuum chemical vapor deposition) process, may be used to form a silicon epitaxial layer. In other embodiments of the present invention, an epitaxial layer comprising silicon and germanium may be formed using, for example, dichlorosilane (SiH₂Cl₂) and germane (GeH₄) through a low pressure chemical vapor deposition at a temperature of, for example, 500 to 800° C. and under a low pressure. In other embodiments, an epitaxial layer comprising silicon and carbon may be formed using, for example, SiH₄ and methylsilane (SiH₃CH₃) through a low pressure chemical vapor deposition at a temperature of, for example, 500 to 800° C. and under a low pressure. The epitaxial layer may be formed with dopants together during the epitaxial growth process or be lightly doped using an ion implantation after the epitaxial growth, to adjust the threshold voltage (Vₜ) of the MOS transistor device.

Since the epitaxial layer grows from a crystal structure layer by layer upwardly to get thicker, the crystal lattice formed will be similar to the lattice of the exposed semiconductor substrate. The insulation region 16, such as a shallow trench isolation, comprises amorphous oxide material, and does not offer a growth place for the epitaxial layer, and the epitaxial layer will not grow from it. Therefore, in the method according to the present invention, the selective epitaxial growth is performed entirely on the semiconductor substrate, and it is sufficient to perform the SEG once to conveniently obtain the epitaxial layer on the desired place of the semiconductor substrate. It is not necessary for the epitaxial growth to be performed in stages or using an assist of patterned masks. It is noted that, in the method according to the present invention, the epitaxial layer grows upwardly from the surface of the active region, as well as gradually grows in lateral direction from the sidewall of the just-obtained epitaxial layer, and thus the finally obtained epitaxial layer has a peripheral portion extending onto the surface of a peripheral portion of the insulation region 16. As such, the channel width of the transistor device is increased and the drain current can be improved.

After the epitaxial layer is formed, an anneal process may be further performed to recover the lattice in defect.

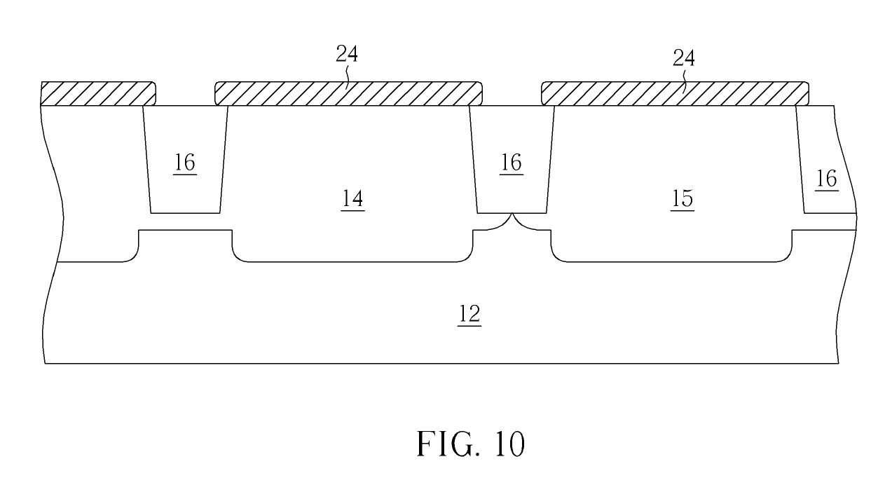

Thereafter, a doped well is formed to obtain a structure as shown in FIG. 10. A P type dopants and an N type dopant as desired may be implanted into the silicon layer 12 respectively using a mask in an implantation process, forming a P type well 14 and a N type well 15, respectively. The doping process is performed after the epitaxial layer 24 is formed, but does not affect the epitaxial layer. An anneal process may be further performed on the epitaxial layer to recover the lattice in defect.

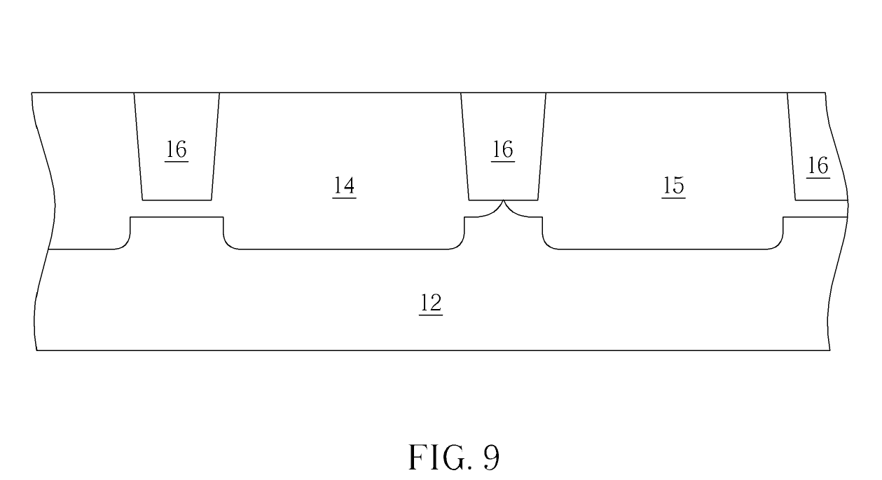

Alternatively, the well is formed before the epitaxial layer is formed. As shown in FIG. 9, an epitaxial layer is not formed immediately after the insulation layer 16 is formed, but a well 14 and 15 are formed in the insulation region 16 of the semiconductor substrate instead. Thereafter, please refer to FIG. 10. A selective epitaxial growth process is performed on the wells 14 and 15 to form an epitaxial layer 24 as described above.

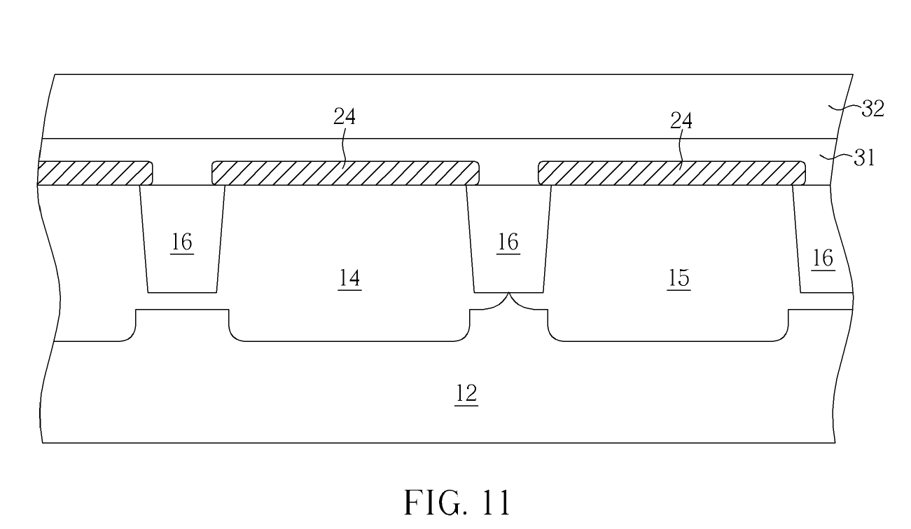

After the selective epitaxial layer is formed, elements, such as gate structures, may be formed on the epitaxial layer. Please refer to FIG. 11. First, a dielectric layer, such as a silicon oxide layer 31 or the like, is deposited on the insulation region 16 and the epitaxial layer 24. A conductive layer, such as a polysilicon layer 32 or the like is formed on the silicon oxide layer 17. Thereafter, a gate structure comprising the silicon oxide layer as a gate insulation layer 18 and the polysilicon layer as a gate electrode layer 20 can be formed using a photolithography and an etching process.

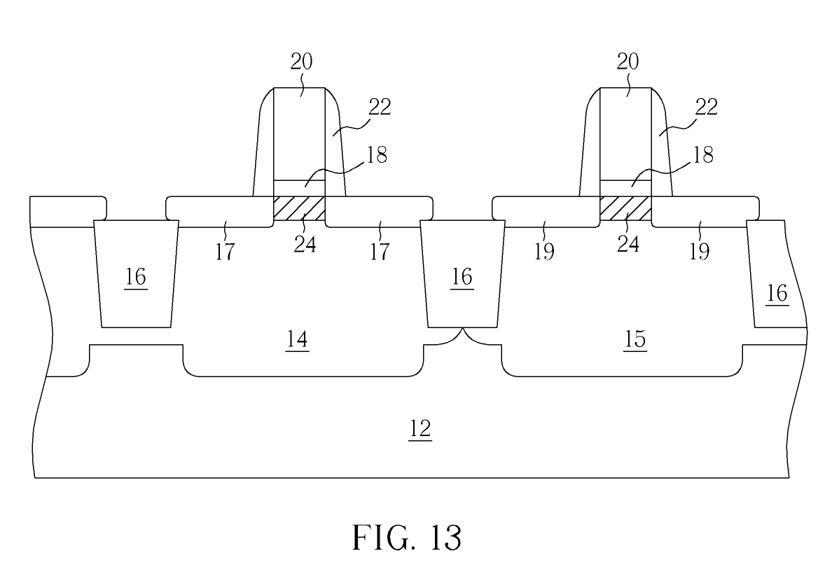

After the gate structure is formed, source/drain regions may be formed in the epitaxial layer and the well at two sides of the gate structure. For example, a lightly doped drain (LDD) process may be performed. Please refer to FIG. 13, a shallow-junction source/drain extension 17 and a shallow-junction source/drain extension 19, may be formed in the epitaxial layer 24 and the wells 14 and 15 at two sides of the gate structure, respectively. Thereafter, a spacer 22 may be formed on sidewalls of the gate electrode layer 20 and the gate insulation layer 18. The spacer may comprise, for example, silicon nitride, silicon oxide or the like. Before forming the spacer 22, a liner may be formed to be between the spacer and the gate structure. The liner may comprise silicon oxide.

After forming the spacer 22, an ion implantation process is carried out to dope dopant species, such as N type dopant species (such as arsenic, antimony or phosphorous) for making an NMOS or P type dopant species (such as boron) for making a PMOS, into the silicon layer 12, thereby forming a source/drain regions 26, 27 of an NMOS device and a drain/source regions 28, 29 of a PMOS device. After the source/drain doping, the substrate may be subjected to an annealing and/or activation thermal process that is known in the art.

A metal silicide layer 25 may be further selectively formed on the exposed silicon surface of the gate electrode layer 20, the exposed source/drain regions 26, 27, 28, and 29. The process known as self-aligned silicide (salicide) process may be utilized to fabricate metal silicide layer, in which a source/drain region is first formed, a metal layer is formed on the source/drain region and the gate structure, and a rapid thermal process (RTP) is performed to react the metal layer with the silicon contained within the gate structure and the drain/source regions to form a metal silicide. The temperature for RTP may be between 700 and 1000° C.

The spacers 22 may be kept in the structure or removed. After the spacers 22 are removed, approximately L shaped liners are left. The liners are not limited to the L shape. A mild etching process may be performed to slightly etch the liner for reducing the thickness. In other embodiments, the liner may be completely stripped away.

Strained silicon or other semiconductor manufacturing techniques may be further performed. For example, a contact etch stop layer (CESL) 23, such as a conformal silicon nitride cap layer, may be formed on the semiconductor substrate. The CESL 32 may be deposited in a compressive-stressed status (for example, −0.1 Gpa to −3 Gpa) for a PMOS or in a tensile-stressed status (for example, 0.1 Gpa to 3 Gpa) for an NMOS to render the channel region a compressive strain or a tensile strain, to improve carrier mobility in the channel, and thus to improve the I_{d}. The stress status of the CESL 23 may be accomplished by thermal treatment, UV radiation, plasma enhanced chemical vapor deposition, or other methods known to those skilled in the art.

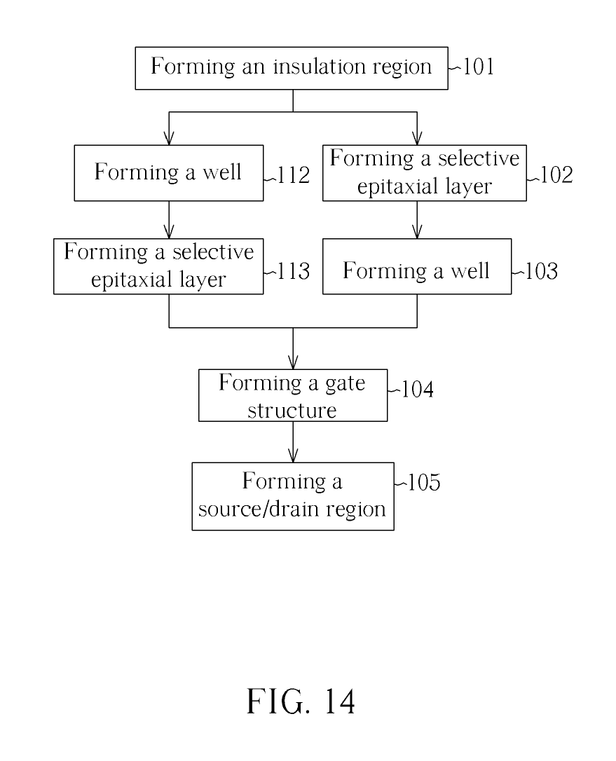

FIG. 14 shows a flow chart illustrating embodiments of the method of manufacturing the MOS transistor device according to the present invention. In brief, the method comprises steps of, first, performing a step 101 on the semiconductor substrate to form an insulation region; next, a step 102 may be performed to form a selective epitaxial layer and then a step 103 is performed to form a well, or a step of 112 is performed to form a well and then a step of 113 is performed to form a selective epitaxial layer; thereafter, a step 104 is performed to form a gate structure on the epitaxial layer; and finally, a step 105 is performed to form a source/drain region in the semiconductor substrate and the epitaxial layer at two sides of the gate structure.

In another embodiment of the method according to the present invention, an epitaxial layer is formed after the well is formed. In such case, the order of forming the insulation region and forming the well is not particularly limited. For example, the step 112 may be performed first to form a well, then the step 101 is performed to form an insulation region, and thereafter the step 113 is performed to form a selective epitaxial layer.

Accordingly, it is noted that in the method of manufacturing a MOS transistor device, the step of forming a selective epitaxial layer should be after the insulation region is formed and before the gate structure is formed.

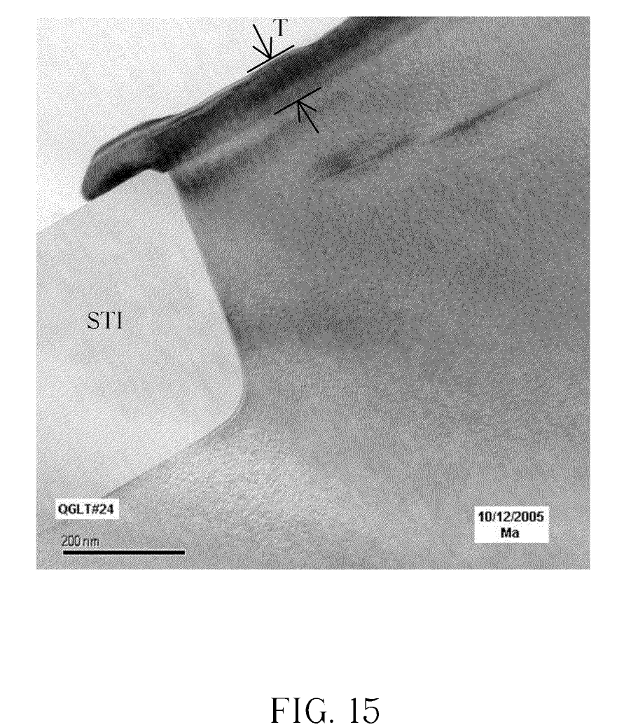

FIG. 15 shows a transmission electron microscope photograph of a semi-finished product after the epitaxial layer is formed in an embodiment of the method according to the present invention. It shows the result of selectively forming an epitaxial layer on the semiconductor substrate in accordance with the method of manufacturing a MOS transistor device according to the present invention. The selective epitaxial growth is performed using an AMAT epi tool (Applied Material Inc., USA) by RPCVD under 15 torr with 200 sccm of dichlorosilane, 0.04 slm (standard liter per minute) of HCl, and 30 slm of H₂. The epitaxial layer thus obtained has a thickness T of about 70 nm. The peripheral portion of the epitaxial layer extends onto the shallow trench isolation (STI) adjacent to the active region and cover the peripheral portion of the shallow trench isolation. The extending distance is about 140 nm.

The embodiment described above is one example of the method of the present invention and there are various modifications. For example, a MBE (molecular beam epitaxy) or UHVCVD (ultra high vacuum chemical vapor deposition) process may be used to replace the RPCVD, or SiH₄ may be used to replace dichlorosilane.

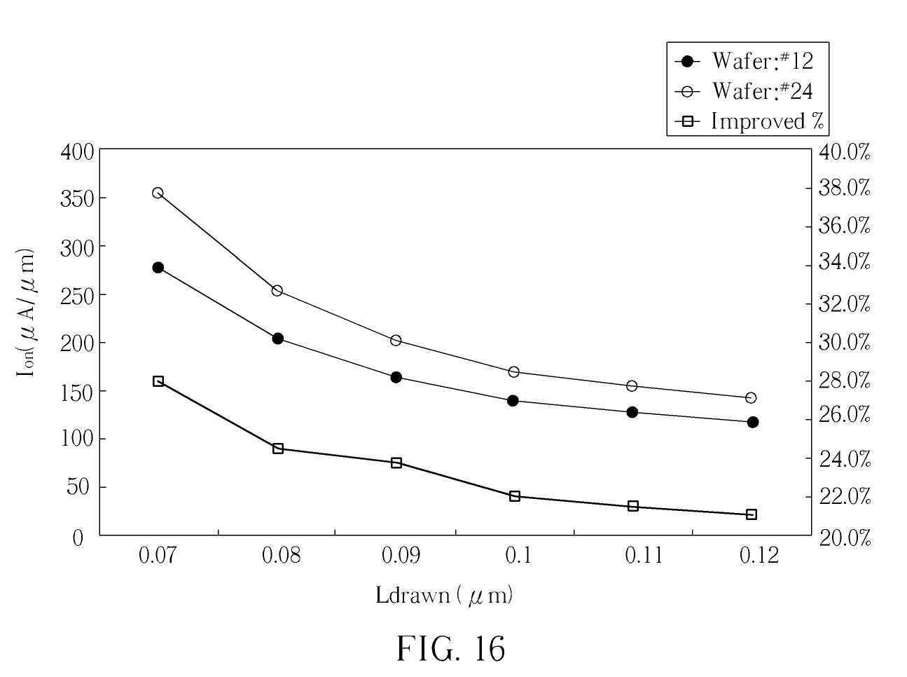

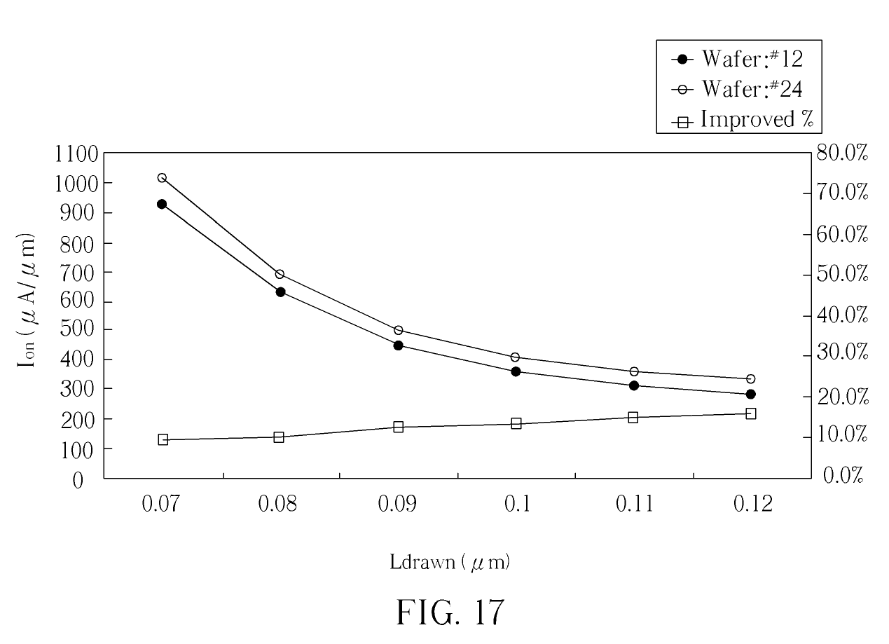

The wafer number 24 having a selective epitaxial layer and an insulation region obtained from the embodiment described above is used to manufacture a high voltage P type MOS (HVT PMOS) transistor device and a HVT NMOS. The wafer number 12 without a selective epitaxial layer is used to manufacture a high voltage P type MOS (HVT PMOS) transistor device and a HVT NMOS. The transistor devices made from the wafers number 24 and number 12 are compared with each other. Both have a same channel length. With a same channel length (Ldrawn), under an voltage application of 1V, as shown in FIG. 16, the HVT PMOS transistor device made from the wafer number 24 has a current (Ion) more than the HVT PMOS made from the wafer number 12. When Ldrawn is 0.07, the Iₒₙ is improved by about 28%, and When Ldrawn is 0.12, the Iₒₙ is improved by about 21%. As shown in FIG. 17, the HVT NMOS transistor device made from the wafer number 24 has a current (Iₒₙ) more than the HVT NMOS made from the wafer number 12. When Ldrawn is 0.07, the Iₒₙ is improved by about 9.6%, and when Ldrawn is 0.12, the Iₒₙ is improved by about 16%.

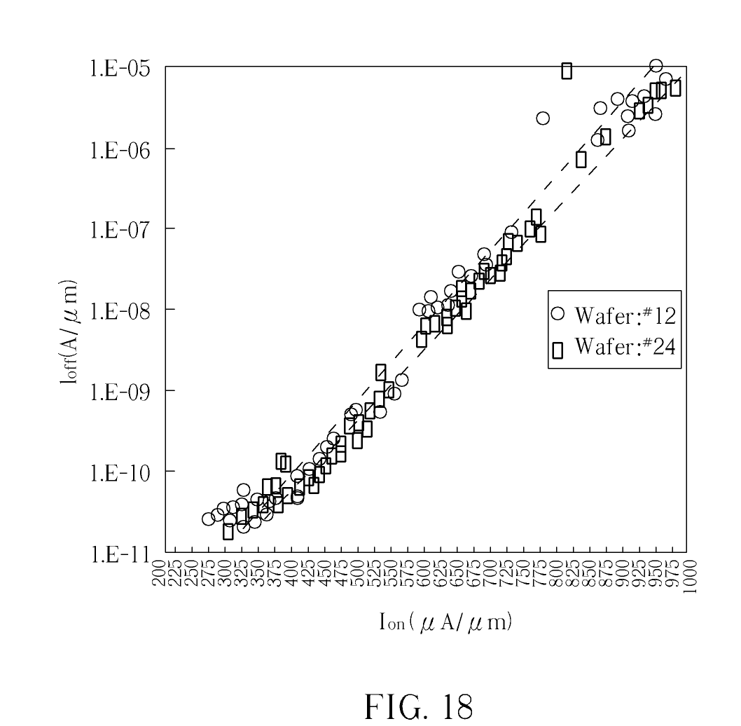

FIG. 18 shows a universal curve obtained by plotting off current (I_{off}) versus on current (Iₒₙ) of the HVT NMOS transistor devices obtained from the wafers number 24 and 12 with various channel lengths. It is shown that, at the same I_{off}, the transistor device obtained using the method of the present invention has a relatively high Iₒₙ.

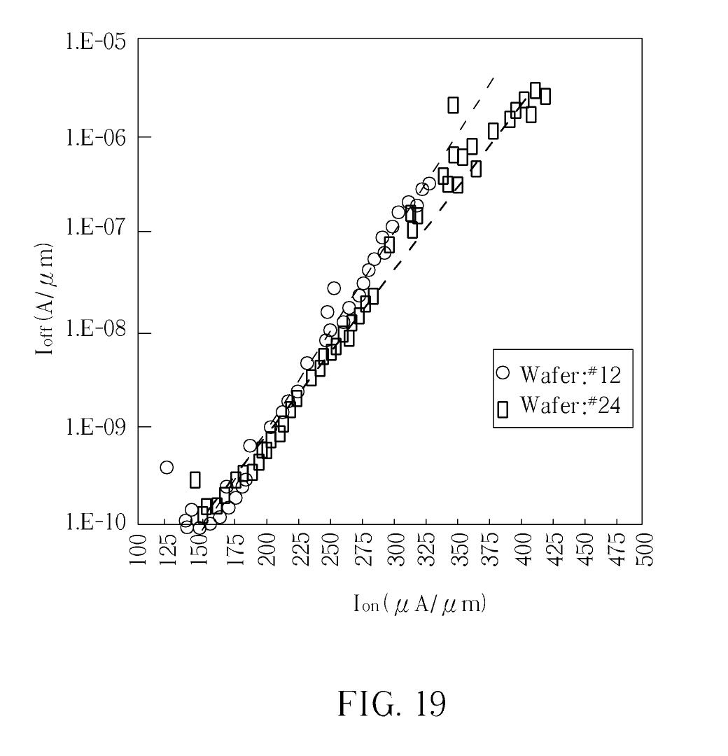

FIG. 19 shows a universal curve obtained by plotting off current (I_{off}) versus on current (Iₒₙ) of the HVT PMOS transistor devices obtained from the wafers number 24 and 12 with various channel lengths. It is shown that, at the same I_{off}, the transistor device obtained using the method of the present invention has a relatively high Iₒₙ.

All combinations and sub-combinations of the above-described features also belong to the present invention. Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing a metal-oxide-semiconductor transistor device, comprising:
providing a semiconductor substrate;
forming an insulation region to define the insulation region and an active region, wherein the active region is adjacent to the insulation region and electrically insulated by the insulation region;
performing a selective epitaxial process to form an epitaxial layer on the active region, wherein the epitaxial layer laterally extends onto a surface of a peripheral portion of the insulation region;
forming a doped well in the semiconductor substrate of the active region;
forming a gate structure on the epitaxial layer; and
forming a drain/source region in the semiconductor substrate and the epitaxial layer at a side of the gate structure.

2. The method of claim 1, wherein the epitaxial layer comprises Si or SiGe.

3. The method of claim 1, wherein the epitaxial layer comprises SiC.

4. The method of claim 1, further comprising lightly doping the epitaxial layer.

5. The method of claim 1, further comprising annealing the epitaxial layer.

6. The method of claim 1, wherein the gate structure comprises a gate electrode layer and a gate insulation layer between the gate electrode layer and the semiconductor substrate.

7. The method of claim 1, after forming the gate structure, further comprising forming a spacer on the sidewall of the gate structure.

8. The method of claim 1, wherein the insulation region comprises a shallow trench isolation.

9. The method of claim 1, wherein forming the drain/source region comprises forming a lightly doped region and a doped region.

10. The method of claim 1, further forming a metal salicide layer on a surface of the drain/source region and a surface of the gate structure.

11. The method of claim 1, further comprising forming a contact etch stop layer covering the drain/source region.
